(19) United States
(12) Patent Application Publication
(10) Pub. No.: US 2025/0210780 A1
(43) Pub. Date: Jun. 26, 2025

(54) ELECTRICAL CABINET AND ENERGY STORAGE CONTAINER

(71) Applicant: Jinko Energy Storage Technology Co., Ltd., Haining City (CN)

(72) Inventors: Shaorong GE, Haining City (CN); Guochao CHEN, Haining City (CN); Xiang WANG, Haining City (CN)

(21) Appl. No.: 18/762,623

(22) Filed: Jul. 2, 2024

(30) Foreign Application Priority Data
Dec. 22, 2023 (CN) 202311785243.6
Dec. 22, 2023 (CN) 202311785248.9

(51) Int. Cl. H01M 50/251; H01M 50/209; H01M 50/256; H01M 50/264; H01M 50/583

(52) U.S. Cl. CPC H01M 50/251; H01M 50/209; H01M 50/256; H01M 50/264; H01M 50/583; H01M 2200/103; H01M 2220/10

(57) ABSTRACT

Provided are an electrical cabinet and an energy storage container, relating to the field of energy storage. The electrical cabinet is used for an energy storage system, and includes a cabinet body, a first mounting plate and a second mounting plate. The first mounting plate includes a first fixed end and a first rotating end. The first fixed end has one end fixed to the cabinet body and another end fixed to the first mounting plate. The first rotating end can rotate around the first fixed end by 90°, and the first mounting plate is configured to mount alternating current devices and direct current device. The second mounting plate is located below the first mounting plate and includes a second fixed end and a second rotating end. The second fixed end has one end fixed to the cabinet body and another end fixed to the second mounting plate.

### CROSS REFERENCE TO RELATED APPLICATIONS

The present application claims the benefit of priority under the Paris Convention to Chinese Patent Application No. 202311785248.9 filed on Dec. 22, 2023 and to Chinese Patent Application No. 202311785243.6 filed on Dec. 22, 2023, each of which is incorporated herein by reference in its entirety.

### TECHNICAL FIELD

The various embodiments described in this document relate in general to the field of energy storage, and more specifically to an electrical cabinet and an energy storage container.

### BACKGROUND

In an energy storage system, an energy storage container system is mainly used in wind, light, storage or microgrid projects due to its integration of flexibility, economy, high efficiency and safety. The energy storage container system features high energy density, small footprint, easy mounting, short construction period, and easy movement and transportation, and can meet most needs of customers by standardized components and flexible configuration of system capacity. Thus, the energy storage container system has been widely used.

The more the number of batteries in the energy storage system, the higher the energy density of the energy storage system. However, the more the number of batteries, the more space the energy storage system takes up. Thus, there is currently a need to provide an electrical cabinet with higher integration to reduce the space occupied by the electrical cabinet.

### SUMMARY

Embodiments of the present disclosure provide an electrical cabinet and an energy storage container, which can at least increase the integration of the electrical cabinet.

According to some embodiments of the present disclosure, one aspect of the embodiments of the present disclosure provides an electrical cabinet for an energy storage system. The electrical cabinet includes a cabinet body, a first mounting plate and a second mounting plate. The first mounting plate includes a first fixed end and a first rotating end. The first fixed end has one end fixed to the cabinet body and another end fixed to the first mounting plate. The first rotating end is rotatable around the first fixed end, and the first mounting plate is configured to mount alternating current devices and direct current devices. The second mounting plate is located below the first mounting plate and includes a second fixed end and a second rotating end. The second fixed end has one end fixed to the cabinet body and another end fixed to the second mounting plate. The second rotating end is rotatable around the second fixed end. The second mounting plate is configured to move away from the first mounting plate in response to being rotated and to mount alternating current protectors and direct current protectors.

In some embodiments, the first mounting plate is configured to move toward the second mounting plate in response to being rotated.

In some embodiments, the electrical cabinet further includes a power supply module, a switch, an input/output (I/O) module and a relay. The power supply module is located at a first corner of the first mounting plate. The switch is located at a second corner of the first mounting board, and the switch and the power supply module are located on a same side of the first mounting plate. The input/output (I/O) module is located at a third corner of the first mounting board, and the I/O module and the switch are located on different sides of the first mounting plate. The relay is located at a fourth corner of the first mounting plate, and the relay and the I/O module are located on a same side of the first mounting plate.

In some embodiments, the electrical cabinet further includes a first terminal block and a second terminal block. The first terminal block is fixed to the first mounting plate and located between the power supply module and the I/O module. The second terminal block is fixed to the first mounting plate and located between the switch and the relay.

In some embodiments, the electrical cabinet further includes a plurality of first binding rods and a second binding rod. The plurality of first binding rods are mounted on the second mounting plate. The plurality of first binding rods extend in a direction oriented from the first mounting plate to the second mounting plate, are arranged in a direction perpendicular to the direction oriented from the first mounting plate to the second mounting plate, and divide a mounting region on the second mounting plate into a first mounting region, a second mounting region and a third mounting region arranged at intervals in sequence. The second binding rod is mounted on the second mounting plate. The second binding rod extends in the direction perpendicular to the direction oriented from the first mounting plate to the second mounting plate, and is located on a side of the plurality of first binding rods away from the first mounting plate.

In some embodiments, the electrical cabinet further includes a plurality of direct current fuses, a plurality of alternating current fuses, a plurality of direct current surge protectors, and an alternating current surge protector. The plurality of direct current fuses are fixed in the first mounting region of the second mounting plate and arranged in the direction oriented from the first mounting plate to the second mounting plate. The plurality of alternating current fuses are fixed in the second mounting region of the second mounting plate and arranged in the direction oriented from the first mounting plate to the second mounting plate. The plurality of direct current surge protectors are fixed in the third mounting region of the second mounting plate and arranged in the direction oriented from the first mounting plate to the second mounting plate. The alternating current surge protector is fixed in the third mounting region of the second mounting plate and located between adjacent ones of the plurality of direct current surge protectors.

In some embodiments, the first fixed end includes a damping hinge configured to slow a rotation rate of the first mounting plate, or the second fixed end includes a damping hinge configured to slow a rotation rate of the second mounting plate. Alternatively, the first fixed end includes a damping hinge configured to slow a rotation rate of the first mounting plate, and the second fixed end includes a damping hinge configured to slow a rotation rate of the second mounting plate.

In some embodiments, the first rotating end includes a fixture detachably connected to the cabinet body and configured to be disconnected from the cabinet body in response to the first mounting plate being to be rotated, or the second rotating end includes a fixture detachably connected to the cabinet body and configured to be disconnected from the cabinet body in response to the second mounting plate being to be rotated. Alternatively, the first rotating end includes a fixture detachably connected to the cabinet body and configured to be disconnected from the cabinet body in response to the first mounting plate being to be rotated, and the second rotating end includes a fixture detachably connected to the cabinet body and configured to be disconnected from the cabinet body in response to the second mounting plate being to be rotated.

In some embodiments, the fixture of the first rotating end includes a screw configured to be taken out in response to the first mounting plate being to be rotated, or the fixture of the second rotating end includes a screw configured to be taken out in response to the second mounting plate being to be rotated. Alternatively, the fixture of the first rotating end includes a screw configured to be taken out in response to the first mounting plate being to be rotated, and the fixture of the second rotating end includes a screw configured to be taken out in response to the second mounting plate being to be rotated.

In some embodiments, the electrical cabinet further includes a handle fixed on a side of the first mounting plate adjacent to the first rotating end, or a handle fixed on a side of the second mounting plate adjacent to the second rotating end. Alternatively, the electrical cabinet further includes a handle fixed on a side of the first mounting plate adjacent to the first rotating end, and a handle fixed on a side of the second mounting plate adjacent to the second rotating end.

According to some embodiments of the present disclosure, another aspect of the embodiments of the present disclosure provides an energy storage container. The energy storage container includes the electrical cabinet as described above.

### BRIEF DESCRIPTION OF THE DRAWINGS

One or more embodiments are exemplarily described with reference to the corresponding figures in the accompanying drawings, and the exemplary descriptions are not to be construed as limiting the embodiments. Unless otherwise particularly stated, the figures in the accompanying drawings are not drawn to scale. To describe technical solutions of embodiments of the present disclosure more clearly, the following briefly introduces the accompanying drawings required for the embodiments. Apparently, the accompanying drawings show only some embodiments of the present disclosure, and a person of ordinary skill in the art may still derive other drawings from these accompanying drawings without creative efforts.

FIG. 1 is a schematic structure view illustrating an electrical cabinet according to embodiments of the present disclosure.

FIG. 2 is another schematic structure view illustrating an electrical cabinet according to embodiments of the present disclosure.

FIG. 3 is still another schematic structure view illustrating an electrical cabinet according to embodiments of the present disclosure.

FIG. 4 is a schematic structure view illustrating a trace groove according to embodiments of the present disclosure.

FIG. 5 is another schematic structure view illustrating a trace groove according to embodiments of the present disclosure.

FIG. 6 is a schematic perspective view illustrating an electrical cabinet accommodating an uninterruptible power supply (UPS).

FIG. 7 is a schematic perspective view illustrating a structure including a front plate, a back plate, a bottom plate and a pressing plate in an electrical cabinet according to embodiments of the present disclosure.

FIG. 8 is a sectional view illustrating a partial structure of the front plate in the electrical cabinet according to embodiments of the present disclosure.

FIG. 9 is a sectional view illustrating a partial structure of the back plate in the electrical cabinet according to embodiments of the present disclosure.

FIG. 10 is a schematic perspective view illustrating a structure including a first rail, a second rail and a third rail in the electrical cabinet.

FIG. 11 is a schematic perspective view illustrating the structure including the front plate, the back plate, the bottom plate and the pressing plate in the electrical cabinet according to embodiments of the present disclosure, with an UPS accommodated in the structure.

FIG. 12 is a simple block diagram illustrating a host in an UPS according to embodiments of the present disclosure.

### DETAILED DESCRIPTION OF THE EMBODIMENTS

It can be known from the background that it is necessary to increase the integration of the electrical cabinet at present.

Embodiments of the present disclosure provide an electrical cabinet. By arranging a first mounting plate and a second mounting plate in the cabinet body, on the one hand, components in the cabinet body are installed by the first mounting plate and the second mounting plate, so that the mounting of the structure in the cabinet body can be facilitated, and the mounting space in the cabinet body can be increased by arranging the first mounting plate and the second mounting plate. On the other hand, the integration of the components in the cabinet body can be increased by arranging the first mounting plate and the second mounting plate, so that the size of the cabinet body of the electrical cabinet itself can be reduced, thereby reducing the space occupied by the electrical cabinet. In addition, the first mounting plate is provided to be rotatable around the first fixed end, and the second mounting plate is provided to be rotatable around the second fixed end, which facilitates the mounting of components behind the first mounting plate and the second mounting plate.

Various embodiments of the present disclosure are described in detail below in connection with the accompanying drawings. However, a person of ordinary skill in the art can understand that in the various embodiments of the present disclosure, a number of technical details have been proposed in order to enable the reader to better understand the present disclosure. However, even without these technical details and various variations and modifications based on the following embodiments, claimed technical solutions of the present disclosure can be implemented.

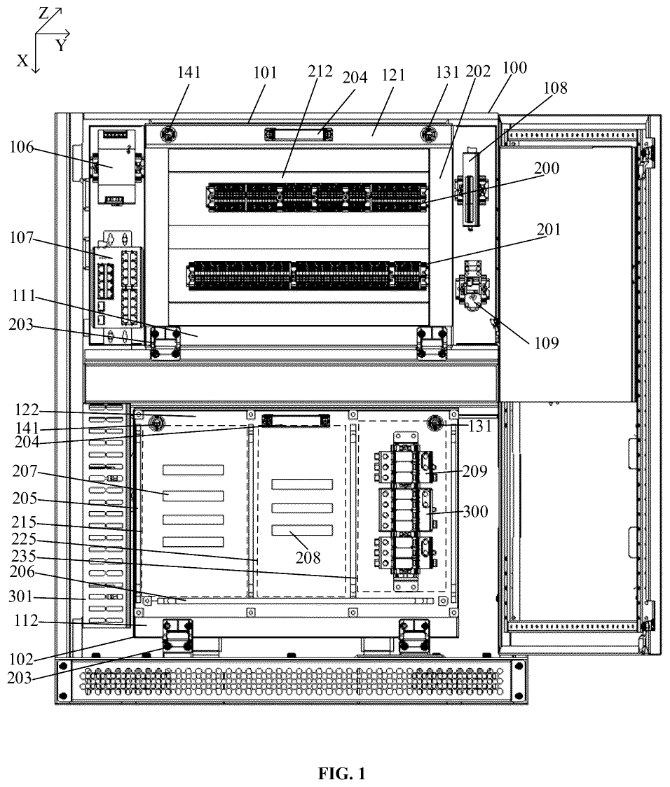

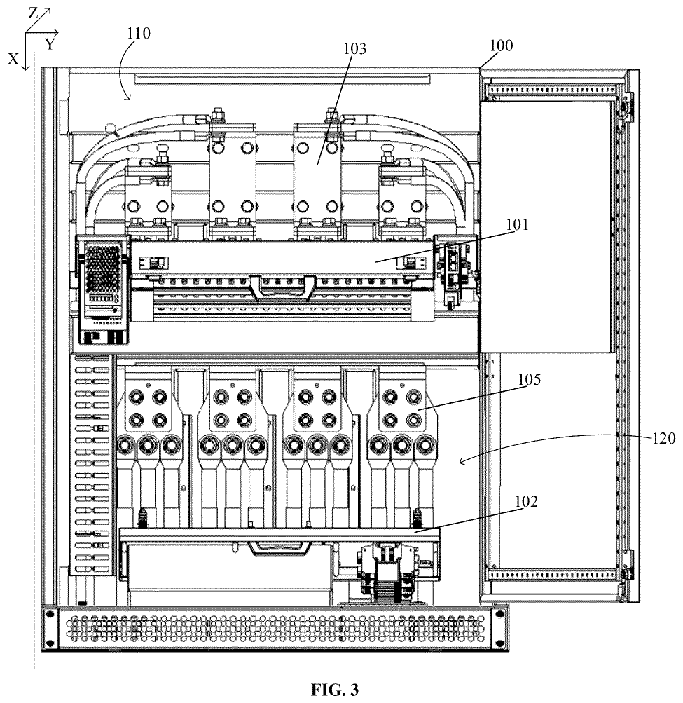

Referring to FIGS. 1 and 3, FIG. 1 is a schematic structure view illustrating the first mounting plate and the second mounting plate before being rotated according to embodiments of the present disclosure, and FIG. 3 is a schematic structure view illustrating the first mounting plate and the second mounting plate after being rotated according to embodiments of the present disclosure.

In some embodiments, the electrical cabinet may include a cabinet body 100.

In some embodiments, the electrical cabinet may further include a first mounting plate 101. The first mounting plate 101 includes a first fixed end 111 and a first rotating end 121. The first fixed end 111 has one end fixed to the cabinet body 100. The first rotating end 121 is rotatable around the first fixed end 111, and the first mounting plate 101 is configured to mount alternating current devices and direct current devices.

In some embodiments, the electrical cabinet may further include a second mounting plate 102. The second mounting plate 102 is located below the first mounting plate 101, and includes a second fixed end 112 and a second rotating end 122. The second fixed end 112 has one end fixed to the cabinet body 100. The second rotating end 122 is rotatable around the second fixed end 112. the second mounting plate is configured to move away from the first mounting plate when rotated and to mount alternating current protectors and direct current protectors.

In the embodiments of the present disclosure, by arranging the first mounting plate 101 and the second mounting plate 102 in the cabinet body 100, on the one hand, components in the cabinet body 100 are installed by means of the first mounting plate 101 and the second mounting plate 102, so that the mounting of the structure in the cabinet body 100 can be facilitated, and the mounting space in the cabinet body 100 can be increased by arranging the first mounting plate 101 and the second mounting plate 102. On the other hand, the integration of the components in the cabinet body 100 can be increased by arranging the first mounting plate 101 and the second mounting plate 102, so that the size of the cabinet body of the electrical cabinet itself can be reduced, thereby reducing the space occupied by the electrical cabinet. In addition, the first mounting plate 101 is provided to be rotatable around the first fixed end 111, and the second mounting plate 102 is provided to be rotatable around the second fixed end 112, which facilitates the mounting of components behind the first mounting plate 101 and the second mounting plate 102.

It should be noted that orientational or positional relationships indicated by technical terms “center,” “longitudinal,” “transverse,” “length,” “depth,” “thickness,” “above,” “below,” “front,” “back,” “left,” “right,” “vertical,” “horizontal,” “top,” “bottom,” “inside,” “outside,” “clockwise,” “anticlockwise” and the like are based on orientational or positional relationships illustrated in the drawings, which are merely intended to facilitate and simplify the description of the present disclosure. These orientational or positional relationships do not indicate or imply that an apparatus or component referred to has a specific orientation and is constructed and operated in a specific orientation, and thus are not to be construed as limiting the present disclosure.

In some embodiments, the cabinet body 100 may include an upper space 110 and a lower space 120, where the first mounting plate 101 may be mounted in the upper space 110 and the second mounting plate 102 may be mounted in the lower space 120.

In some embodiments, the cabinet body 100 may include a bracket and a base plate fixed to the outside of the bracket. The bracket may divide the cabinet body into the upper space 110 and the lower space 120, and the first rotating end 121 of the first mounting plate 101 may be fixed to the bracket. The first rotating end 121 may be detachably fixed to the bracket. When the first rotating end 121 is fixed to the bracket, the first mounting plate 101 can not be rotated, and at this time, mounting of components on the first mounting plate 101 is enabled. When the first rotating end 121 is not fixed to the bracket, the first mounting plate 101 can be rotated around the first fixed end 111, in other words, when it is necessary to install the components behind the first mounting plate 101, the first rotating end 121 may be disconnected from the bracket, so that the first mounting plate 101 is rotatable around the first fixed end 111 and the mounting of the components behind the first mounting plate 101 is enabled.

In some embodiments, the first rotating end 121 may include a fixture 131 detachably connected to the cabinet body 100. The fixture 131 is configured to be disconnected from the cabinet body 100 in response to the first mounting plate 101 being to be rotated. The connection and disconnection between the first mounting plate 101 and the cabinet body 100 are controlled by the fixture 131, so that the mounting of the components behind the first mounting plate 101 or the mounting of the components on the first mounting plate 101 can be performed according to demand.

In some embodiments, the fixture 131 includes a screw 141 configured to be taken out in response to the second mounting plate 101 being to be rotated. Fixing by means of the screw 141 can provide a certain reliability between the fixture 131 and the cabinet body 100, and facilitate the overhaul or replacement of the fixture 131, thereby facilitating the replacement of components in the whole electrical cabinet.

In some embodiments, the fixture 131 may also be a magnet, so that the first rotating end 121 can be fixed to the bracket by magnetic attraction. By providing the fixture 131 as a magnet, the connection and disconnection between the first rotating end 121 and the bracket can be facilitated, thereby facilitating the mounting of components in the electrical cabinet.

In some embodiments, a direction oriented from the first mounting plate 101 to the second mounting plate 102 is defined as a first direction X, a direction perpendicular to the first direction is defined as a second direction Y, and a direction oriented from the first mounting plate 101 to the back is defined as a third direction Z.

In some embodiments, the first mounting plate 101 is configured to move toward the second mounting plate 102 when rotated, that is, the first mounting plate 101 may be rotated with the second direction Y as the axis, so that the mounting of components behind the first mounting plate 101 is enabled after the first mounting plate 101 is rotated to open.

In some embodiments, the first mounting plate 101 may have a rotation angle of 0 to 90°, so that the first mounting plate 101 can be prevented from interfering with the operation of the second mounting plate 102 while the first mounting plate 101 is rotated to a maximum angle.

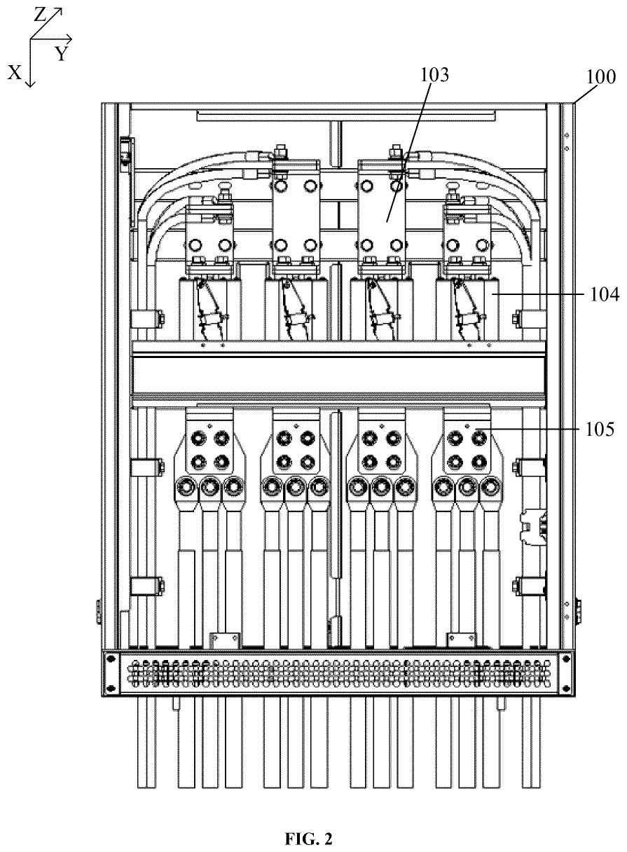

Referring to FIG. 2, FIG. 2 is a schematic structure view illustrating the electrical cabinet with the first mounting plate and the second mounting plate removed according to embodiments of the present disclosure.

In some embodiments, the components behind the first mounting plate 101 may include: first busbars 103, fuses 104, and second busbars 105. The first busbars 103 are configured to collect currents of battery packs in the container. The container includes battery packs and a high-voltage box. The high-voltage box can control collecting and outputting of currents of a respective column of battery packs. The respective column of battery packs is connected to the high-voltage box which is connected to a respective first busbar 103 through a positive cable and a negative cable, so that currents are collected on the respective first busbar 103. The respective first busbar 103 is electrically connected to a respective fuse 104 which is then electrically connected to the second busbar 105, so that the collected currents are output through the second busbar 105.

Referring to FIGS. 1 to 3, when the first mounting plate 101 is rotated open, the first busbars 103 behind the first mounting plate 101 can be exposed, so that the first busbars 103 and the positive cables and the negative cables can be mounted. When the second mounting plate 102 is rotated open, the second busbars 105 behind the second mounting plate 102 can be exposed, so that the second busbars 105 and output cables can be mounted. After the mounting, the first mounting plate 101 and the second mounting plate 102 can be fixed, so that the first busbars 103, the fuses 104 and the second busbars 105 behind the first mounting plate 101 and the second mounting plate 102 can be covered. By providing each of the first mounting plate 101 and the second mounting plate 102 as a rotatable structure, on the one hand, the connection of the first busbars 103, the fuses 104 and the second busbars 105 behind the first mounting plate 101 and the second mounting plate 102 can be facilitated while improving the integration of the components in the electrical cabinet. On the other hand, after the mounting, the mounted positive cables, negative cables, first busbars 103, fuses 104 and second busbars 105 can be protected, thereby avoiding the influence of other subsequent mountings on the mounted positive cables, negative cables, first busbars 103, fuses 104 and second busbars 105.

In some embodiments, the electrical cabinet includes not only the cabinet body 100 but also a cabinet door facing the cabinet body 100. The cabinet door can be rotated with the first direction X as the axis. The cabinet door of the electrical cabinet is provided to have a rotation direction different from rotation directions of the first mounting plate 101 and the second mounting plate 102, so that the first mounting plate 101 and the second mounting plate 102 can be prevented from interfering with the cabinet door when rotated. For example, if the cabinet door has a rotation direction same as the rotation directions of the first mounting plate 101 and the second mounting plate 102, there may be a situation in which the first mounting plate 101 and the second mounting plate 102 cannot be fully opened, resulting in interference between the cabinet door and the first and second mounting plates 101, 102, and affecting the mounting of the components behind the first mounting plate 101 and the second mounting plate 102.

In addition, the first mounting plate 101 is provided to be rotatable towards the second mounting plate 102, so that the mounting area of the first mounting plate 101 can be increased without interfering with other structures. It may be understood that if the first mounting plate 101 is rotated with the first direction X as the axis, there are the following three cases. In a first case, counterclockwise rotation is performed with the first direction X as the axis: if the first mounting plate 101 is rotated counterclockwise with the first direction X as the axis, when opened, the first mounting plate 101 may be interfered with the door cabinet, resulting in the first mounting plate 101 not being able to be opened to a maximum angle, which may affect the mounting of the components behind the first mounting plate 101. In a second case, clockwise rotation is performed with the first direction X as the axis: if the first mounting plate 101 is rotated clockwise with the first direction X as the axis, like the situation in which the first mounting plate 101 is rotated counterclockwise with the first direction X as the axis, the first mounting plate 101 may be interfered with the door cabinet. In a third case, side-by-side doors are provided with the first direction X as the axis: if the first mounting plate 101 includes side-by-side doors with the first direction X as the axis, for the mounting space of the first mounting plate 101, the maximum mounting length on the first mounting plate 101 is a length of one of the side-by-side doors. It is to be understood that opening and closing of the first mounting plate 101 are needed, therefore, the components mounted on the first mounting plate 101 should not affect the opening and closing of the first mounting plate 101, that is, the components on the first mounting plate 101 cannot extend across two doors. Therefore, for the first mounting plate 101, the maximum mounting space for a single component is an area of one of the doors, resulting in the first mounting plate 104 not being able to mount relatively large components. Therefore, by providing the first mounting plate 101 to be rotatable toward the second mounting plate 102, the mounting area of the first mounting plate 101 can be increased without interfering with other structures.

With continued reference to FIG. 1, in some embodiments, the electrical cabinet may further include: a power supply module 106, a switch 107, an input/output (I/O) module 108, and a relay 109. The power supply module 106 is located at a first corner of the first mounting plate 101. The switch 107 is located at a second corner of the first mounting plate 101, and the switch 107 and the power supply module 106 are located on the same side of the first mounting plate 101. The I/O module 108 is located at a third corner of first mounting plate 101, and the I/O module 108 and the switch 107 are located on different sides of the first mounting plate 101. The relay 109 is located in a fourth corner of the first mounting plate 101, and the relay 109 and the I/O module 108 are located on the same side of the first mounting plate 101.

The power supply module 106 can provide power to the switch 107, the I/O module 108 and the relay 109. The switch 107 can be used for communication in the electrical cabinet, the I/O module 108 can be used for signal acquisition, data transmission and control, and the relay 109 can be used for automatic adjustment, safety protection, conversion circuits, etc. The power supply module 106, switch 107, I/O module 108, and relay 109 serve as alternating current devices and direct current devices.

In some embodiments, the electrical cabinet may further include a first terminal block 200 and a second terminal block 201. The first terminal block 200 is fixed to the first mounting plate 101 and located between the power supply module 106 and the I/O module 108. The second terminal block 201 is fixed to the first mounting plate 101 and located between the switch 107 and the relay 109. The first terminal block 200 and the second terminal block 201 are configured to mount traces inside the electrical cabinet. For example, the power supply module 106 may be electrically connected to the I/O module 108, the trace of the power supply module 106 may be connected to the first terminal block 200, thereby enabling the power supply module 106 to be electrically connected to the I/O module 108. In some embodiments, in order to increase the integration of components in the electrical cabinet, there are also components mounted on the cabinet door of the electrical cabinet, and thus, the components on the cabinet door of the electrical cabinet may also be electrically connected to the first terminal block 200. The second terminal block 201 serves the same purpose as the first terminal block 200, i.e., facilitating mounting of the traces within the electrical cabinet.

In some embodiments, there is also included a trace groove 202 mounted on the first mounting plate 101. The trace groove 202 defines two accommodating spaces 212 that are separated from each other. The first terminal block 200 and the second terminal block 201 may be fixed in two accommodating spaces 212. On the one hand, the positions of the first terminal block 200 and the second terminal block 201 are limited by the trace groove 202 to facilitate the mounting of the first terminal block 200 and the second terminal block 201, and on the other hand, traces connected to the first terminal block 200 and the second terminal block 201 can be fixed, thereby regularizing the traces connected to the first terminal block 200 and the second terminal block 201.

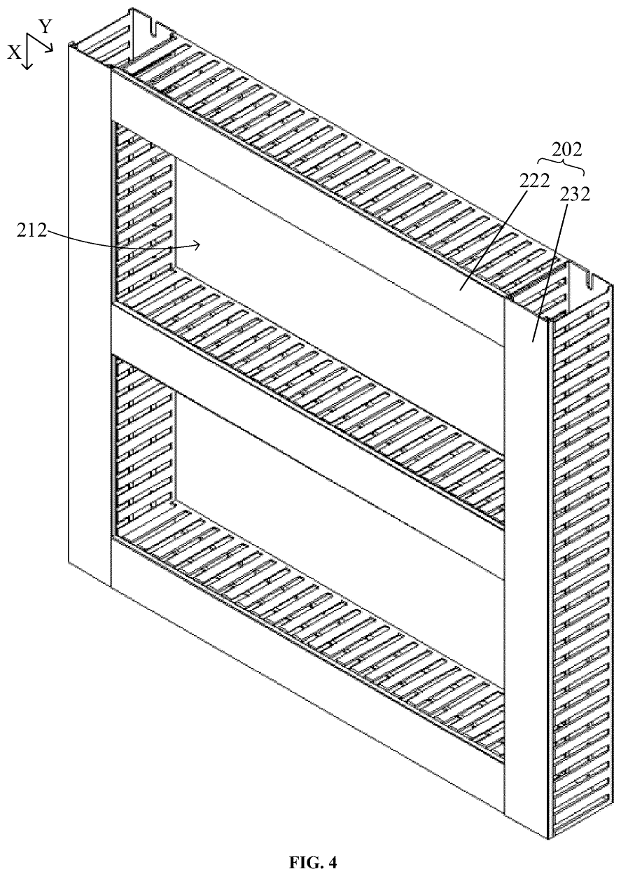

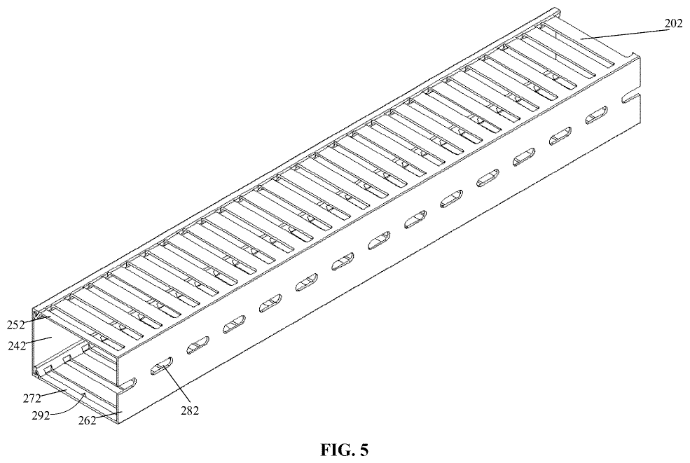

With reference to FIGS. 4 and 5, FIG. 4 is a schematic structure view illustrating a trace groove according to embodiments of the present disclosure, and FIG. 5 is a schematic structure view illustrating another first trace groove or second trace groove according to embodiments t of the present disclosure.

In some embodiments, the trace groove 202 may include first trace grooves 222 arranged in the first direction X and extending in the second direction Y, and second trace grooves 232 arranged in the second direction Y and extending in first direction X. The first trace grooves 222 and the second trace grooves 232 are fixed to the first mounting plate 101. The first direction X and the second direction Y may be perpendicular to each other.

In some embodiments, the trace groove 202 may include: a first side plate 242, a second side plate 252, a third side plate 262, and a fourth side plate 272 connected in sequence, where the first side plate 242 is directly opposite the third side plate 262, the second side plate 252 is directly opposite the fourth side plate 272, and the third side plate 262 includes a plurality of mounting holes 282. The trace groove 202 may be secured to the first mounting plate 101 through the mounting holes 282, and the second side plate 252 and the fourth side plate 272 each include a plurality of trace holes 292. The trace holes 292 in the second side plate 252 and the trace holes 292 in the fourth side plate 272 may be directly opposite to each other. The trace holes 292 in the fourth side plate 272 may face the first terminal block 200 and second terminal block 201, and the trace holes 292 in the second side plate 252 may face alternating and direct current devices that needs electrical connection, so that the first terminal block 200 and second terminal block 201 can be connected to the alternating and direct current devices that needs electrical connection through the trace holes 292 in the second side plate 252 and the fourth side plate 272, thereby controlling the components within the integrated cabinet.

In some embodiments, a length of the first terminal block 200 in the second direction Y may be less than a length of the second terminal block 201. In other embodiments, a length of the first terminal block 200 in the second direction Y may be greater than or equal to a length of the second terminal block 201. The lengths of the first terminal block 200 and the second terminal block 201 may be selected according to the practical needs.

In some embodiments, the length of the first terminal block 200 in the second direction Y may be greater than or equal to ⅔ of the length of the first mounting plate 101 in the second direction Y, and the length of the second terminal block 201 in the second direction Y may be greater than or equal to the length of the first mounting plate 101 in the second direction Y. It is to be understood that in order to reduce the size of the electrical cabinet to increase the integration of the electrical cabinet, the arrangement density of components within the electrical cabinet would be increased, while the electrical cabinet is still fully equipped with functional components. That is, although the accommodating space in the electrical cabinet is reduced, the number of the functional components in the electrical cabinet is not reduced. Accordingly, terminal blocks are needed, and the reduced mounting space would result in the reduction of the mounting regions of the terminal blocks. Thus, by providing the length of the first terminal block 200 in the second direction Y to be greater than or equal to ⅔ of the length of the first mounting plate 101 in the second direction Y and providing the length of the second terminal block 201 in the second direction Y to be greater than or equal to ⅔ of the length of the first mounting plate 101 in the second direction Y, sufficient mounting space for the traces of the components in the electrical cabinet can be provided, thereby ensuring normal function operations in the electrical cabinet while adapting to reduction of the size of the electrical cabinet.

In some embodiments, the first fixed end 111 may further include a damping hinge 203. The first fixed end 111 is fixed to the cabinet body 100 by the damping hinge 203. The damping hinge 203 is configured to slow down a rotation rate of the first mounting plate 101. It is to be understood that multiple components are mounted on the first mounting plate 101 and there are also traces on the first mounting plate 101. By providing the damping hinge 203, a too large rotation rate of the first mounting plate 101 can be avoided, thereby avoiding impacting the traces and components on the first mounting plate 101. In this manner, the reliability within the electrical cabinet can be improved.

In some embodiments, the number of damping hinges 203 connected to the first fixed end 111 may be two, and two damping hinges are provided so that the problem of unstable rotation of the first mounting plate 101 can be avoided during rotation of the first mounting plate 101 and the cost can be reduced.

In some embodiments, the first fixed end 111 may also be fixed to the cabinet body 100 by other means.

In some embodiments, the electrical cabinet may also include a handle 204 fixed on a side of the first mounting plate 101 adjacent to the first rotating end 121. With the handle 204, the first rotating end 121 can be controlled to be rotatable around the first fixed end 111. In addition, a rate at which the first rotating end 121 rotates around the first fixed end 111 can also be controlled by the handle 204, thereby avoiding a too large rotation rate of the first rotating end 121 and thus avoiding damage to components on the first mounting plate 101 due the too large rotation rate.

In some embodiments, the second rotating end 122 may further include a fixture 131 detachably connected to the cabinet body 100. The fixture 131 is configured to be disconnected from the cabinet body 100 in response to the second mounting plate 102 being to be rotated. The connection and disconnection between the second mounting plate 102 and the cabinet body 100 are controlled by the fixture 131 so that the mounting of the components behind the second mounting plate 102 or mounting of the components on the second mounting plate 102 can be performed according to demand.

In some embodiments, the fixture 131 includes a screw 141 configured to be taken out in response to the second mounting plate 102 being to be rotated. Fixing by means of the screw 141 can provide a certain reliability between the fixture 131 and the cabinet body 100, and facilitate the overhaul or replacement of the fixture 131, thereby facilitating the replacement of components in the whole electrical cabinet.

In some embodiments, the fixture 131 may also be a magnet, related descriptions of which can be referred to the above description of the fixture 131 on the first mounting plate 101, and will not be repeated below.

In some embodiments, the positions of the fixture 131 mounted on the first mounting plate 101 and the positions of the fixture 131 mounted on the second mounting plate 102 are arranged in an array.

In some embodiments, there are a plurality of fixtures 131. Taking as an example the fixture 131 being a screw 141, the number of screws 141 may be, for example, 2, 3, or 4, and positions of the screws 141 may be symmetrically disposed along the first direction X.

In some embodiments, the first mounting plate 101 may have a depth of 250 mm to 300 mm in the first direction X, for example, 260 mm, 270 mm, 280 mm, or 290 mm. The first mounting plate 101 may have a length of 450 mm to 500 mm in the second direction Y, for example, 460 mm, 470 mm, 480 mm or 490 mm. The first mounting plate 101 is provided to have a depth of 250 mm to 300 mm in the first direction X and a length of 450 mm to 500 mm in the second direction Y so that the first mounting plate 101 has sufficient large mounting space while the size of the first mounting plate 101 is reduced.

In some embodiments, the electrical cabinet may further include a plurality of first binding rods 205 and a second binding rod 206 that are mounted on the second mounting plate 102. The plurality of first binding rods 205 extend in a direction oriented from the first mounting plate 101 to the second mounting plate 102, are arranged in a direction perpendicular to the direction oriented from the first mounting plate 101 to the second mounting plate 102, and divide a mounting region on the second mounting plate 102 into a first mounting region 215, a second mounting region 225 and a third mounting region 235 arranged at intervals in sequence. The second binding rod 206 extends in the direction perpendicular to the direction oriented from the first mounting plate 101 to the second mounting plate 102, and is located on a side of the plurality of first binding rods 205 away from the first mounting plate 101.

In other words, the first binding rods 205 extend in the first direction X and are spaced apart from each other along the second direction Y, and the second binding rod 206 extends in the second direction Y. The first binding rods 205 and the second binding rod 206 are provided so that the setting of traces on the second mounting plate 102 can be facilitated. The traces can be bound by the first binding rods 205 and the second binding rod 206 so that the clutter of the traces on the second mounting plate 102 can be avoided, entanglement between the traces and other components can be avoided, and the space occupied by the traces can be reduced to improve the integration within the electrical cabinet.

In some embodiments, the electrical cabinet may further include a plurality of direct current fuses 207, a plurality of alternating current fuses 208, a plurality of direct current surge protectors 209 and an alternating current surge protector 300. The plurality of direct current fuses 207 are fixed in the first mounting region 205 of the second mounting plate 102 and arranged in the direction oriented from the first mounting plate 101 to the second mounting plate 102. The plurality of alternating current fuses 208 are fixed in the second mounting region 225 of the second mounting plate 102 and arranged in the direction oriented from the first mounting plate 101 to the second mounting plate 102. The plurality of direct current surge protectors 209 are fixed in the third mounting region 235 of the second mounting plate 102 and arranged in the direction oriented from the first mounting plate 101 to the second mounting plate 102. The alternating current surge protector 300 is fixed in the third mounting region 235 of the second mounting plate 102 and located between adjacent ones of the plurality of direct current surge protectors 209.

The plurality of direct current fuses 207 are provided so that the direct current devices in the electrical cabinet are protected, and the plurality of alternating current fuses 208 are provided so that the alternating current devices in the electrical cabinet are protected. The plurality of direct current surge protectors 209 are provided so that the components in the electrical cabinet can be effectively protected from damage when an overvoltage occurs in the direct current circuit, thereby avoiding equipment damage caused by the overvoltage. The alternating current surge protector 300 is provided so that a surge current can be limited so as to protect the components in the electrical cabinet.

Fixing the plurality of direct current fuses 207 in the first mounting region 215 can facilitate the electrical connection between the plurality of direct current fuse 207 and the direct current devices in the electrical cabinet. Fixing the plurality of alternating current fuses 208 in the second mounting region 225 can facilitate the electrical connection between the plurality of alternating current fuses 208 and the alternating current devices in the electrical cabinet. Fixing the plurality of direct current surge protectors 209 and the alternating current surge protector 300 in the third mounting region 235 can facilitate the protection of the components in the whole electrical cabinet by the plurality of direct current surge protectors 209 and the alternating current surge protector 300. In addition, the alternating current surge protector 300 is disposed between adjacent direct current surge protectors 209 so that direct current surge protection and alternating current surge protection can be alternatingly performed, thereby further improving the reliability of the components in the electrical cabinet.

In some embodiments, the second fixed end 112 may further include a damping hinge 203. The second fixed end 112 is fixed to the cabinet body 100 by the damping hinge 203. The damping hinge 203 is configured to slow down a rotation rate of the second mounting plate 102. It is to be understood that multiple components are mounted on the second mounting plate 102 and there are also traces on the second mounting plate 102. By providing the damping hinge 203, a too large rotation rate of the second mounting plate 102 can be avoided, thereby avoiding affecting the traces and components on the second mounting plate 102. In this manner, the reliability within the electrical cabinet can be improved.

In some embodiments, the electrical cabinet may further include a handle 204 fixed on a side of the second mounting plate 102 adjacent to the second rotating end 122. With the handle 204, the second rotating end 122 can be controlled to be rotatable around the second fixed end 112. In addition, a rate at which the second rotating end 122 rotates around the second fixed end 112 can also be controlled by the handle 204, thereby avoiding a too large rotation rate of the second rotating end 122 and thus avoiding damage to components on the second mounting plate 102 due the too large rotation rate.

In some embodiments, the second mounting plate 102 may have a depth of 250 mm to 300 mm in the first direction X, for example, 260 mm, 270 mm, 280 mm, or 290 mm. The second mounting plate 102 may have a length of 350 mm to 400 mm in the second direction Y, for example, 370 mm, 390 mm, 410 mm or 430 mm. The second mounting plate 102 is provided to have a depth of 250 mm to 300 mm in the first direction X and a length of 350 mm to 400 mm in the second direction Y so that the second mounting plate 102 sufficient large mounting space while the size of the second mounting plate 102 is reduced.

In some embodiments, the electrical cabinet may further include a wire-hiding plate 301. The wire-hiding plate 301 may be disposed on one or both of opposite sides of the second mounting plate 102 in the second direction Y. On the one hand, the wire-hiding plate 301 may be configured to mount traces on one side or both sides of the second mounting plate 102. The wire-hiding plate 301 includes a plurality of through holes through which the traces pass, so that position limiting of the traces is enabled through the through holes. On the other hand, the wire-hiding plate 301 also shields a part of the structure within the cabinet body, thereby improving the aesthetics within the cabinet body of the electrical cabinet by the wire-hiding plate 301.

It is to be understood that the first mounting plate 101 has the first terminal block 200 and the second terminal block 201 mounted thereon, and therefore, the first mounting plate 101 does not need the wire-hiding plate 301 to assist in the mounting of the traces, while the second mounting plate 102 does not have sufficient space to place terminal blocks. Therefore, providing the wire hiding plate 301 on at least one side of the second mounting plate 102 can assist the mounting of the traces on the second mounting plate 102, and can also provide more space for the traces, thereby reducing the space required to be occupied by the second mounting plate 102 and then reducing the size of the electrical cabinet.

To sum up, in the embodiments of the present disclosure, the arrangement of components in the entire electrical cabinet is adjusted so that the integration of components in the electrical cabinet is increased, and the space occupied by the electrical cabinet can be reduced. This provides a basis for subsequent mounting of more battery packs in the container, thereby allowing for an increase in energy density in the container.

In the embodiments of the present disclosure, the first mounting plate 101 and second mounting plate 102 are provided in the cabinet body 100 so that on the one hand, components in the cabinet body 100 are mounted by the first mounting plate 101 and the second mounting plate 102, facilitating the mounting of the structure in the cabinet body 100, and the mounting space in the cabinet body 100 can be increased by arranging the first mounting plate 101 and the second mounting plate 102. On the other hand, the integration of the components in the cabinet body 100 can be increased by arranging the first mounting plate 101 and the second mounting plate 102, so that the size of the cabinet body 100 of the electrical cabinet itself can be reduced, thereby reducing the space occupied by the electrical cabinet. In addition, the first mounting plate 101 is provided to be rotatable around the first fixed end 111, and the second mounting plate 102 is provided to be rotatable around the second fixed end 122, which facilitates the mounting of components behind the first mounting plate 101 and the second mounting plate 102.

Another embodiment of the present disclosure also provides a container including the electrical cabinet in any one of some or all of the above embodiments. It is to be noted that parts same or corresponding to those in the foregoing embodiments may be referred to the corresponding descriptions of the foregoing embodiments, which will not be repeated below.

In some embodiments, the container may include 6 columns of battery packs and a high voltage box located below the 6 battery packs. The high voltage box is configured to collect currents of the 6 columns of battery packs and transmit the collected currents to the electrical cabinet. The high voltage box may be electrically connected to the first busbars 103, so that the first busbars 103 collect currents from the high voltage box and output the currents by the second busbars 105.

With the rapid growth of China's economy, the problem of tight national power supply is becoming more and more prominent, so the development and utilization of renewable energy have received widespread attention in recent years. Especially with the increase of electricity demand in China, the use of various electrical cabinets is increasing.

However, with the increasing demand for high energy storage density in the field of energy storage, the size of the electrical cabinet is further compressed, which in turn makes the space reserved for an uninterruptible power supply (UPS) in the electrical cabinet further compressed. The type of the UPS and the placement of the UPS in the electrical cabinet affect the way the UPS is placed in the electrical cabinet, thereby affecting to a certain extent the convenience of an operator in installing and removing the UPS in the electrical cabinet.

From the above, it can be seen that the convenience of the operator in installing and removing the UPS in the electrical cabinet is desired to be improved.

After analysis, it is found that the existing UPS mainly consists of a main unit and storage batteries, and it is very troublesome to maintain the main unit and the storage batteries installed in the electrical cabinet. Specifically, firstly, it is necessary to remove peripheral fixed components of the main unit or storage batteries, and then move the heavy main unit or storage batteries out of the electrical cabinet. Both the removal and maintenance of the heavy main unit and storage batteries are inconvenient.

Furthermore, due to a different product type of the UPS, when the core structure of a storage battery in the UPS is to be replaced, a different operation is required for the storage battery. Currently, the main unit and the storage batteries in the UPS are placed in a way that the main unit and the storage batteries in the UPS are stacked on one another in a vertical direction, in other words, in a cabinet height direction of the electrical cabinet.

In some cases, limited by the product types of the UPS, a housing of a storage battery at a side of the storage battery facing a cabinet door of the electrical cabinet cannot be disassembled individually, and it is necessary to take the storage batteries out of the electrical cabinet as a whole, and then disassemble the housing of the storage battery to replace the core structure in the storage battery.

In other cases, based on the characteristics of the product types of the UPS, the side of the storage battery facing the cabinet door of the electrical cabinet is provided with a cover plate that can be individually removed to expose the core structure in the storage battery. Therefore, in replacement of the core structure of the storage battery by the operator, it is not necessary to take the storage battery out of the electrical cabinet, but remove the cover plate alone to pull out the exposed core structure of the storage battery horizontally.

As can be seen, due to the different product type of the UPS, the core structure of the storage battery in the UPS may be replaced in a very different way, which is not conducive to a uniform design of the installation and removal process of the UPS, and thus is not conducive to the improvement of the convenience of an operator in installing and removing the UPS in an electrical cabinet.

The present disclosure provides an electrical cabinet and an energy storage container, where the electrical cabinet is designed with an accommodating chamber defined by a front plate, a back plate and a bottom plate. Moreover, the front plate is closer to a cabinet door of the electrical cabinet than the back plate, based on which the front plate is connected to at least one pressing plate by screwing, and the back plate is connected to the at least one pressing plate by insertion. After opening the cabinet door of the electrical cabinet and placing the UPS into the accommodating chamber, without direct contact with the back plate, the operator may pass one end of each respective pressing plate through a respective insertion hole on the back plate along the first direction Z to achieve insertion and fixation of the respective pressing plate to the back plate. Then, a screw is screwed into a respective first screw hole of the front plate to achieve fixation of the respective pressing plate to the front plate, thereby installing the UPS into the electrical cabinet, which is conducive to improving the convenience of installing the UPS in the electrical cabinet. Moreover, the front plate is closer to the electrical cabinet than the back plate, so that the operator can remove the respective pressing plate from the front plate at the door of the cabinet, and without direct contact with the back plate, the operator can remove the respective pressing plate located in the respective insertion hole by pulling the respective pressing plate out of the respective insertion hole in the first direction, which facilitates servicing or replacing the UPS by the operator from the top of the UPS 400, thereby contributing to improving the convenience of the operator in removing the respective pressing plate and the convenience of the operator in servicing or replacing the UPS 400.

Various embodiments of the present disclosure are described in detail below in conjunction with the accompanying drawings. However, a person of ordinary skill in the art may understand that in the various embodiments of the present disclosure, a number of technical details have been proposed to enable a reader to better understand the embodiments of the present disclosure. However, even without these technical details and various changes and modifications based on the embodiments, the claimed technical solutions of the embodiments of the present disclosure can be achieved.

Embodiments of the present disclosure provide an electrical cabinet, and the electrical cabinet according to embodiments of the present disclosure is described in detail below in conjunction with the accompanying drawings.

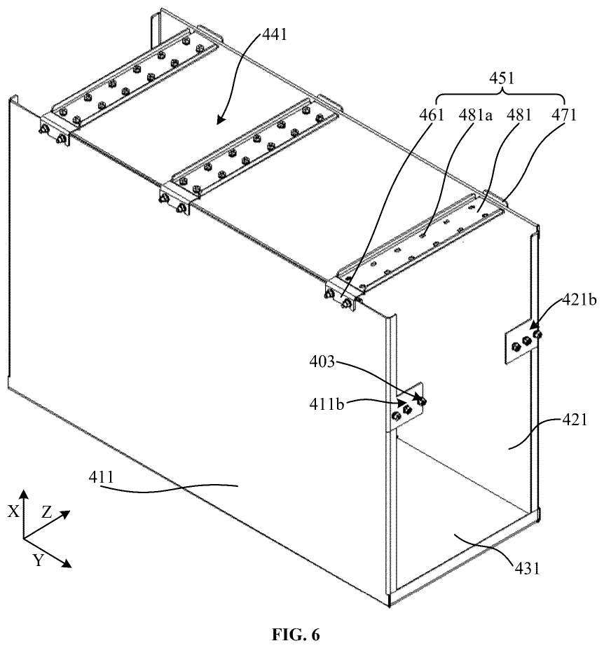

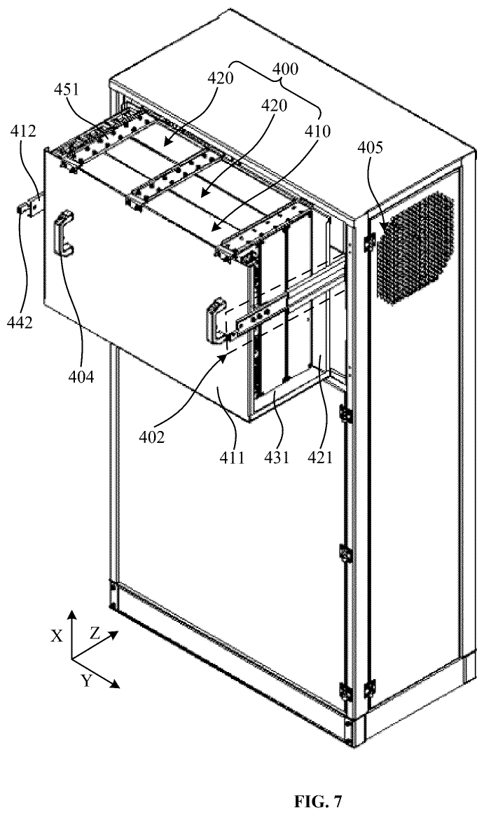

With reference to FIG. 6 and FIG. 7, the electrical cabinet that houses an UPS 400 includes: a front plate 411 and a back plate 421 oppositely arranged along a first direction Z, a bottom plate 431, and pressing plates 451. The first direction Z is a cabinet depth direction of the electrical cabinet, and the front plate 411 is closer to the cabinet door of the electrical cabinet than the back plate 421. The bottom plate 431 connects the front plate 411 to the back plate 421. The front plate 411, the back plate 421 and the bottom plate 431 define an accommodating chamber 441, and the UPS 400 is disposed in the accommodating chamber 441. The pressing plates 451 are disposed on a top surface of the front plate 411 away from the bottom plate 431.

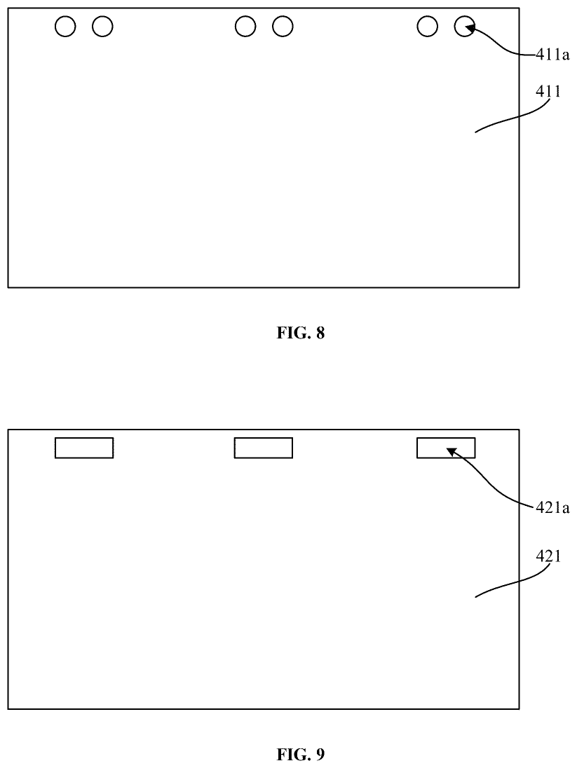

With reference to FIG. 6, FIG. 8 and FIG. 9, the front plate 411 has a number of first screw holes 411a on a top of the front plate 411 away from the bottom plate 431, and the back plate 421 has a number of insertion holes 421a on a top of the back plate 421 away from the bottom plate 431. One end of a respective pressing plate 451 of the pressing plates 451 is fixed to the front plate 411 by the mating of a respective first screw hole 411a with a respective screw 403, and another end of the respective pressing plate 451 passes through a respective insertion hole 421a to achieve position limiting of the respective pressing plate 451 by the back plate 421 through the respective insertion hole 421a.

FIG. 6 is a schematic perspective view illustrating an electrical cabinet accommodating an UPS. FIG. 7 is a schematic perspective view illustrating a structure including a front plate, a back plate, a bottom plate and pressing plates in an electrical cabinet according to embodiments of the present disclosure. FIG. 8 is a sectional view illustrating a partial structure of the front plate in the electrical cabinet according to embodiments of the present disclosure. FIG. 9 is a sectional view illustrating a partial structure of the back plate in the electrical cabinet according to embodiments of the present disclosure.

It is to be noted that the accommodating chamber 441 defined by the front plate 411, the back plate 421 and the bottom plate 431 in the electrical cabinet is designed to accommodate the UPS 400, and the U-shaped plate formed by the front plate 411, the back plate 421 and the bottom plate 431 can be used to carry the UPS 400 and limit the UPS 400 along the first direction Z to prevent the UPS 400 from moving back and forth. Based on this, the respective pressing plate 451 is designed to have a limit relationship with both the front plate 411 and the back plate 421, thereby facilitating the cooperation of the front plate 411, the back plate 421, the bottom plate 431 and the pressing plates 451 to install the UPS 400 in the electrical cabinet. In other words, the structure including the front plate 411, the back plate 421, the bottom plate 431 and the pressing plates 451 shown in FIG. 7 enables fixed mounting of the UPS 400 in the electrical cabinet.

Moreover, the front plate 411 is designed to be closer to the cabinet door of the electrical cabinet than the back plate 421, the front plate 411 is designed to be connected to the pressing plates 451 by screwing, and the back plate 421 is designed be connected to the pressing plates 451 by insertion. In this way, after opening the cabinet door of the electrical cabinet and placing the UPS 400 into the accommodating chamber 441, the operator can pass one end of the respective pressing plate 451 through the respective insertion hole 421a on the back plate 421 in the Z direction, without direct contact with the back plate, so as to achieve fixation of the respective pressing plate 451 to the back plate 421 through insertion. Then, a screw 403 is screwed into the respective first screw hole 411a to achieve fixation of the respective pressing plate 451 to the front plate 411. Thereby, the UPS 400 can be installed in the electrical cabinet. Thus, in the embodiments of the present disclosure, a new structure for installing and fixing the UPS 400 is designed, and the convenience for the operator to achieve the mutual limitation of the respective pressing plate 451 with the front plate 411 and the back plate 421 is improved, so as to improve the convenience of the operator in installing the UPS 400 in the electrical cabinet.

In addition, when the UPS 400 installed in the electrical cabinet is to be serviced or replaced, since the front plate 411 is closer to the cabinet door of the electrical cabinet than the back plate 421, the operator can remove the respective pressing plate 451 from the front plate 411 at the cabinet door, and then take away the respective pressing plate 451 on the top of the UPS 400 by pulling the respective pressure plate 451 out of the respective insertion hole 421a in the first direction X without direct contact with the back plate, which facilitates servicing or replacing the UPS 400 by the operator from the top of the UPS 400, thereby contributing to improving the convenience of the operator in removing the respective pressing plate 451 and the convenience of the operator in servicing or replacing the UPS 400.

Embodiments of the present disclosure are described in more detail below in conjunction with the accompanying drawings.

In some embodiments, referring to FIG. 7, 2 handles 404 are provided on a side of the front plate 411 away from the back plate 421, and the 2 handles 404 are oppositely arranged along the second direction Y. In this way, positions of the 2 handles 404 are adapted to positions of left and right hands of the operator, so that the operator can pull the UPS 400 out of the electrical cabinet by means of the 2 handles 404, which is conducive to further improving the convenience of the operator in installing or removing the UPS 400 in the electrical cabinet.

In some embodiments, with combined reference to FIG. 6 and FIG. 9, the insertion holes 421a are in one-to-one correspondence with the pressing plates 451, with a spacing between adjacent pressing plates 451.

In some embodiments, the pressing plates 451 are equally spaced in the second direction Y. In this way, in achieving the fixation between the pressing plates 451, the front plate 411 and the back plate 421, it is conductive to making points of force application of the respective pressing plate 451 on the front plate 411 evenly distributed along the second direction Y so that the respective pressing plate 451 applies a force uniformly to the front plate 411, thereby avoiding increasing of the layout space occupied by the UPS 400 in the electrical cabinet due to the deformation of the front plate 411.

It should be noted that FIG. 6 and FIG. 7 both take as an example the electrical cabinet including three pressing plates 451 spaced apart along the second direction Y. In practical applications, there is no limitation on the number of pressing plates 451 spaced apart along the second direction Y in the electrical cabinet, which may be selected according to actual needs.

In some embodiments, the U-shaped plate including the front plate 411, the back plate 421 and the bottom plate 431 is an integrally formed structure. For example, the U-shaped plate may be formed by a stamping process or a bending process. In other embodiments, the U-shaped plate may also be a split structure. For example, the front plate 411, the back plate 421 and the bottom plate 431 are fixed to each other by welding to form the U-shaped plate.

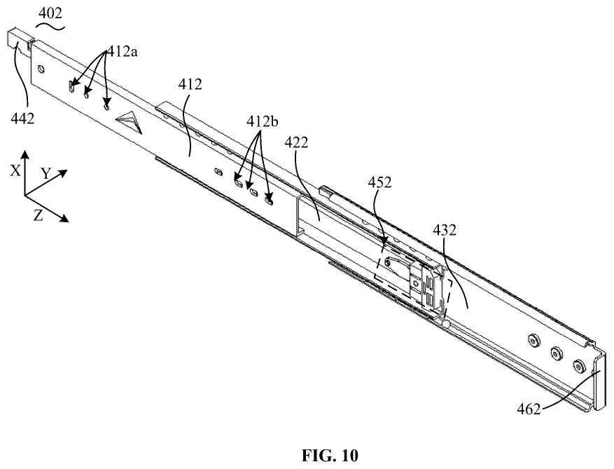

In some embodiments, with combined reference to FIG. 7 and FIG. 10, the electrical cabinet may further include a first rail 412, a second rail 422 and a third rail 432. The first rail 412 has one end fixed to the front plate 411 and the other end fixed to the back plate 421. The second rail 422 is mounted on the first rail 412. The third rail 432 is mounted on the second rail 422 and fixed to the cabinet body of the electrical cabinet.

In this way, the UPS 400 is slidingly connected to the electrical cabinet by means of the first rail 412, the second rail 422 and the third rail 432, so that the operator can directly pull the UPS 400 out of the electrical cabinet by means of a three-section heavy-duty rail 402 including the first rail 412, the second rail 422 and the third rail 432, and then directly inspect the main unit 410 or the storage batteries 420 outside the cabinet door of the electrical cabinet, and if the main unit 410 or the storage batteries 420 need to be removed, the operator can also carry out corresponding operations directly outside the cabinet door of the electrical cabinet, which is conducive to increasing the operating space of the operator, so as to improve the convenience of the operations of the main unit 410 or the storage batteries 420 by the operator.

Moreover, since the UPS 400 can be pulled out of the electrical cabinet, there is no need to reserve an operating space above the UPS 400 in the electrical cabinet for the operator's operations, which is conductive to reducing the overall size of the electrical cabinet, and if the electrical cabinet is used in an energy storage container, it is also conductive to reducing the layout space required by the electrical cabinet in the energy storage container, so that there is more space in the energy storage container to layout the storage batteries so as to increase the energy storage density of the energy storage container.

It should be noted that FIG. 10 is a schematic perspective view illustrating a structure including a first rail, a second rail and a third rail in the electrical cabinet. In addition, a structure framed in a dashed box in FIG. 7 illustrates a three-section heavy-duty rail 402 including the first rail 412, the second rail 422 and the third rail 432.

In some embodiments, with reference to FIG. 6 and FIG. 10, the U-shaped plate including the front plate 411, the back plate 421 and the bottom plate 431 may be slidingly connected to the electrical cabinet in following manner. The front plate 411 has two first bent portions 411b oppositely arranged along the second direction Y and bent towards the back plate 421, the second direction Y is an arrangement direction of the pressing plates 451, and each first bent portion 411b is provided with a number of second screw holes (not shown). The back plate 421 has two second bent portions 421b oppositely arranged along the second direction Y and bent towards the front plate 411, and each second bent portion 421b is provided with a number of third screw holes (not shown). One end of the first rail 412 is fixed to the front plate 411 by mating of screws 403 with second screw holes, and another end of the first rail 412 is fixed to the back plate 421 by the mating of screws with third screw holes.

It is to be noted that the U-shaped plate including the front plate 411, the back plate 421 and the bottom plate 431 is fixed to the first rail 412 by means of the first bent portions 411b and the second bent portions 421b. Since the UPS 400 is fixed in the U-shaped plate including the front plate 411, the back plate 421 and the bottom plate 431, and the third rail 432 is fixed to the cabinet body of the electrical cabinet, the UPS 400 (refer to FIG. 7) can be slidingly connected to the cabinet body of the electrical cabinet by means of the three-section heavy-duty rail 402 including the first rail 412, the second rail 422, and the third rail 432.

In addition, one first bent portion 411b and one second bent portion 421b located on the same side of opposite sides of the U-shaped plate including the front plate 411, the back plate 421 and the bottom plate 431 in the second direction Y are fixed to a same first rail 412, and a third rail 432 corresponding to the first rail 412 is fixed to the cabinet body of the electrical cabinet, so that the U-shaped plate is slidably connected to the electrical cabinet by means of two three-second heavy-duty rails 402 respectively disposed on the two opposite sides of the U-shaped plate in the second direction Y. It is to be noted that one three-section heavy-duty rail 402 includes one first rail 412, one second rail 422 and one third rail 432.

In some embodiments, with reference to FIG. 6, the first bent portion 411b extends along the first direction Z, and the second bent portion 421b extends along the first direction Z.

In some embodiments, with combined reference to FIG. 6, FIG. 7 and FIG. 10, one end of the first rail 412 adjacent to the cabinet door of the electrical cabinet along the first direction Z is provided with a number of first mounting holes 412a corresponding one-to-one with the second screw holes on the respective first bent portion 411b, and screws 403 are passed through the first mounting holes 412a and the second screw holes on the respective first bent portion 411b to achieve the fixation of the first rail 412 to the front plate 411. Another end of the first rail 412 away from the cabinet door of the electrical cabinet along the first direction Z is provided with a number of second mounting holes 412b corresponding one-to-one with the third screw holes on the respective second bent portion 421b, and screws 403 are passed through the second mounting holes 412b and the third screw holes on the respective second bent portion 421b to achieve the fixation of the first rail 412 to the back plate 421. In this way, both the left and right ends of the first rail 412 along the first direction Z are fixed to the U-shaped plate including the front plate 411, the back plate 421 and the bottom plate 431 to achieve the fixation of the first rail 412 to the UPS 400. Then, when the first rail 412 slides relative to the third rail 432, the first rail 412 can drive the UPS 400 to move relative to the electrical cabinet.

It should be appreciated that the third rail 432 may have a number of third mounting holes (not shown) at one end of the third rail 432 adjacent to the cabinet door of the electrical cabinet along the first direction Z, and a number of fourth mounting holes (not shown) at one end of the third rail 432 away from the cabinet door of the electrical cabinet along the first direction Z. Different screws are passed through the third mounting holes or the fourth mounting holes to fix the third rail 432 to the electrical cabinet.

It is to be noted that FIG. 10 illustrates only an example in which one end of the first rail 412 adjacent to the cabinet door of the electrical cabinet in the first direction Z is provided with three first mounting holes 412a spaced apart along the first direction Z and one end of the first rail 412 away from the cabinet door of the electrical cabinet in the first direction Z is provided with three second mounting holes 412b spaced apart along the first direction Z. In practical applications, there is no limitation on the number and arrangement manner of the first mounting holes 412a, and there is also no limitation on the number and arrangement manner of the second mounting holes 412b, which may be adjusted according to actual situations. Similarly, there is no limitation on the numbers and arrangement manners of the third mounting holes and the fourth mounting holes in the third rail 432, which may be adjusted according to actual situations.

In some embodiments, referring to FIG. 10, the electrical cabinet may further include a self-locking mechanism 442 disposed at an end of the first rail 412 away from the front plate 411 and the back plate 421. In this way, when both the first rail 412 and the second rail 422 are slid into a groove of the third rail 432, operating the self-locking mechanism 442, for example, pressing the self-locking mechanism 442 along the third direction X, is conducive to preventing the first rail 412 and the second rail 422 from sliding relative to the third rail 432. Since the third rail 432 is fixed to the cabinet body of the electrical cabinet (refer to FIG. 7), the operator can use the self-locking mechanism 442 to achieve the fixing of the UPS 400 (refer to FIG. 7) to the electrical cabinet, thus facilitating the avoidance of non-human-caused relative sliding of the UPS 400 and the electrical cabinet after the UPS 400 is installed in the electrical cabinet. The third direction X is the direction of the height of the cabinet in the electrical cabinet.

In practical applications, when it is necessary to pull the UPS 400 out of the electrical cabinet, the self-locking mechanism 442 is pressed again along the third direction X to release the relative fixation between the first rail 412, the second rail 422 and the third rail 432.

In some embodiments, with reference to FIG. 10, the electrical cabinet may further include a buffer structure 452 disposed at an end of the second rail 422 away from the self-locking mechanism 442. It is to be noted that, with reference to FIG. 7 and FIG. 10, when it is necessary to push the UPS 400 into the electrical cabinet using the first rail 412, the second rail 422 and the third rail 432, the buffer structure 152 facilitates limiting the sliding speed of the second rail 422 relative to the third rail 432, so as to avoid excessive movement speed of the UPS 400 due to a too large thrust of the operator on the front plate 411, thereby further avoiding a too large movement speed of the UPS 400 resulting in a large impact on the three-section heavy-duty rail 402, so as to improve the service life of the three-section heavy-duty rail 402 including the first rail 412, the second rail 422 and the third rail 432.

In some embodiments, referring to FIG. 10, the electrical cabinet may further include a limiting portion 462. The limiting portion 462 is located at an innermost end of the third rail 432 away from the cabinet door of the electrical cabinet along the first direction Z (referring to FIG. 7), and bent from the third rail 432 toward the UPS 400 (refer to FIG. 7). In this way, as the first rail 412 and the second rail 422 slide into the cabinet interior of the electrical cabinet, the second rail 422 may slide to be abutted against the limiting portion 462, so that the limiting portion 462 can restrict the first rail 412 and the second rail 422 from sliding further into the cabinet interior of the electrical cabinet, to provide the operator with a signal indicating that the UPS 400 is in place.

In some embodiments, with combined reference to FIG. 6 and FIG. 8, the end of the respective pressing plate 451 fixed to the front plate 411 is provided with a first mounting ear 461 bent towards the bottom plate 431. The first mounting ear 461 has fourth screw holes corresponding one-to-one with first screw holes 411a, and a screw 403 penetrates a respective fourth screw hole and a respective first screw hole 411a successively to achieve fixation of the respective pressing plate 451 to the front plate 411. In some embodiments, with combined reference to FIG. 6 and FIG. 9, the end of the respective pressing plate 451 inserted into the back plate 421 is provided with a second mounting ear 471 bent in a direction away from the bottom plate 431, and the second mounting ear 471 is passed through the insertion hole 421a to achieve position limiting of the respective pressing plate 451.

In this way, with the design of the first mounting ear 461, the operating space where the operator fixes the respective pressing plate 451 to the front plate 411 using the screws 403 is located on a side of the front plate 411 away from the back plate 421, i.e. away from the cabinet interior of the electrical cabinet, which is conducive to increasing the operable space of the operator and making it more convenient for the operator to realize the operation of fixing the respective pressing plate 451 to the front plate 411. It is to be noted that when the UPS 400 is located in the accommodating chamber 441, the respective pressing plate 451 is located on the top surface of the UPS 400 in the third direction X. In other words, the respective pressing plate 451 is supported by the UPS 400, based on which the end of the respective pressing plate 451 inserted into the front plate 411 is designed to have the second mounting ear 471 bent in a direction away from the bottom plate 431, and after the respective pressing plate 451 is fixed to the front plate 411 by means of screwing through the first mounting ear 461 and is fixed to the back plate 421 by means of insertion through the second mounting ear 471, the second mounting ear 471 may be abutted against the back plate 421 in the first direction Z, thereby facilitating further prevention of movement of the respective pressing plate 451 relative to the back plate 421.

It should be noted that in the example shown in FIG. 6 and FIG. 8, one pressing plate 451 corresponds to two first screw holes 411a and two fourth screw holes. In actual applications, the number of first screw holes 411a and fourth screw holes corresponding to the same pressing plate 451 can be flexibly adjusted according to actual needs, for example, one, three or four.

In some embodiments, referring to FIG. 6, the respective pressing plate 451 may further include a main body 481 located between the first mounting ear 461 and the second mounting ear 471. The main body 481 has spaced mounting holes 481a, and screws 403 are passed through the mounting holes 481a to achieve fixation of the respective pressing plate 451 to the UPS 400, which is conducive to further improving the limiting effect of the respective pressing plate 451 on the UPS 400. In practical applications, when the UPS includes a main unit and storage batteries, the screws are passed through the mounting holes to achieve fixation of the main unit and the storage batteries.

In some embodiments, with continued reference to FIG. 6, the mounting holes 481a on the main body 481 may be arranged in an array along the first direction Z and the second direction Y. In this way, it is conductive to making points of force application of the respective pressing plate 451 on the main body 410 or the storage batteries 420 evenly distributed so that the respective pressing plate 451 applies force uniformly to the main body 410 or the storage batteries 420, thereby facilitating the avoidance of damage to the main unit 410 or the storage batteries 420.

It should be noted that FIG. 6 only illustrates an example of one arrangement of the mounting holes 481a on the main body 481, and the embodiments of the present disclosure do not exhaust the number and arrangement of mounting holes 481a on the main body 481.

In some embodiments, at least most part of the respective pressing plate 451, such as the main body 481, extends along the first direction Z, and part of the respective pressing plate 451 extending along the first direction Z runs through a spacing between the front plate 411 and the back plate 421 in the first direction Z. In this way, it is conductive to ensuring that one end of the respective pressing plate 451 is fixed to the front plate 411 by the mating of the first screw holes 411a with the screws 403, and another end of the respective pressing plate 451 is passed through the insertion hole 421a to achieve position limiting of the respective pressing plate 451 by the back plate 421 through the insertion hole 421a.

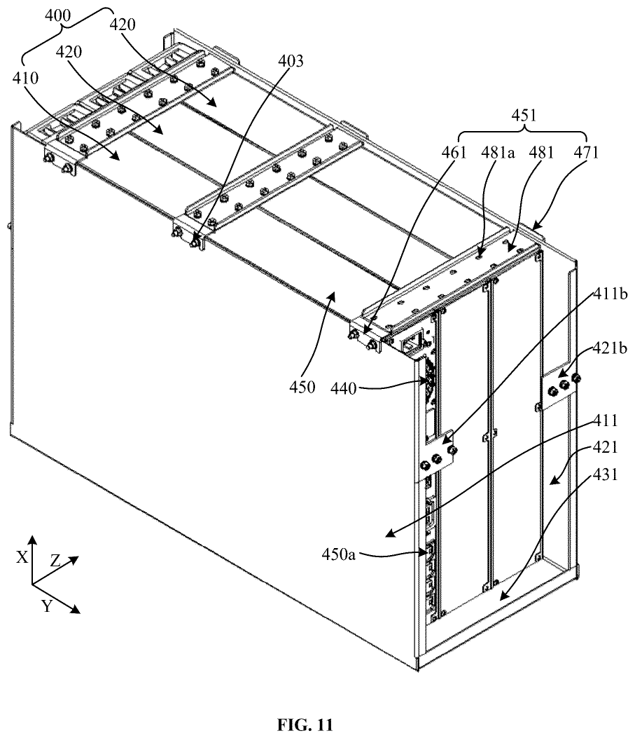

In some embodiments, referring to FIG. 7 and FIG. 11, the electrical cabinet may further include an UPS 400 disposed between the front plate 411 and the back plate 421 and between the pressing plates 451 and the bottom plate 431, and the UPS 400 including a main unit 410 and storage batteries 420 arranged along the first direction Z, where the front plate 411 is adjacent to the cabinet door of the electrical cabinet.

It is to be noted that FIG. 11 is a schematic perspective view illustrating the structure including the front plate, the back plate, the bottom plate and the pressing plates in the electrical cabinet according to embodiments of the present disclosure, with an UPS accommodated in the structure. In addition, parts of FIG. 11 that are identical or similar to those of FIG. 6 are not be repeated herein.

It is to be noted that the first direction Z is an arrangement direction of the main unit 410 and the storage batteries 420 in the UPS 400. In this manner, regardless of the type of the UPS 400, when the UPS 400 needs to be serviced or replaced, the main unit 410 or storage batteries 420 in the UPS 400 are pulled out along the third direction X, and subjected to corresponding repair or replacement, which facilitates the operations of the operator and achieves a uniform design of the installation and removal process of different types of UPS 400.

In some cases, when the main unit 410 or a storage battery 420 fails, the operator needs to remove the main unit 410 or the storage battery 420 from the electrical cabinet; in other cases, the main unit 410 has a longer normal service life than the storage batteries 420, and thus there exists a situation that the storage batteries 420 in the UPS 400 need to be repaired or replaced in order to allow the UPS 400 to continue to operate. In this situation, the operator needs to take the old storage batteries 420 out of the electrical cabinet and put new storage batteries 420 into the electrical cabinet.

Based on this, the main unit 410 and the storage batteries 420 are designed to be placed vertically in the first direction Z, and only at least one pressing plate 451 is located on the top of the main unit 410 and the storage batteries 420 in the third direction X. When it is necessary to service the main unit 410 or the storage batteries 420 or to replace a storage battery 420, the operator only needs to remove the at least one pressing plate 451 from the front plate 411 and the bottom plate 411, and then take the main unit 410 or the storage battery 420 out of the electrical cabinet from above. Thus, the designed placement of the main unit 410 and the storage batteries 420 and the new structure for fixing the UPS 400 facilitate improving the convenience of an operator in servicing the main unit 410 or the storage batteries 420 or replacing the storage batteries 420.

In some embodiments, with reference to FIG. 7 and FIG. 10, the UPS 400 includes the main unit 410 and the storage batteries 420 arranged along the first direction Z, and is slidably connected to the electrical cabinet by means of the first rail 412, the second rail 422 and the third rail 432. Thus, the main unit 410 and the storage batteries 420 are placed vertically in the electrical cabinet in the cabinet depth direction of the electrical cabinet, and after the operator pulls the UPS 400 out of the electrical cabinet with the aid of the pulling device, the main unit 410 or the storage batteries 420 can be pulled out directly from the top of the UPS 400. It is to be noted that, most of the upper part of the UPS 400 is located outside of the electrical cabinet, that is, there is a large operating space for the operator to operate above the UPS 400, which facilitates the activities of the operator.

In some cases, there is a limited extent to which the UPS 400 can be pulled out of the electrical cabinet by means of the first rail 412, the second rail 422 and the third rail 432, in other words, part of the UPS 400 may still be inside the electrical cabinet. Based on this, the front plate 411 is designed to be connected to the pressing plates 451 by screwing, and the back plate 421 is designed be connected to the pressing plates 451 by insertion. In this way, the operator can pinch one end of the respective pressing plate 451 that corresponds to the front plate 411 and pull the remaining part of the respective pressing plate 451 out of the electrical cabinet, without direct contact with the back plate 421, so as to service the main unit 410 or the storage batteries 420 or to replace a storage battery 420. Alternatively, by means of the one end of the respective pressing plate 451 that corresponds to the front plate 411, another end of the respective pressing plate 451 is directly passed through the respective insertion hole 421a, to achieve insertion and fixation of the respective pressing plate 451 to the back plate 421, thereby facilitating improving the convenience of the operator in removing and installing the respective pressing plate 451, and further improving the convenience of the operator in servicing the main unit 410 or the storage batteries 420, replacing a storage battery 420, or installing the UPS 400 into the electrical cabinet.

In some cases, the first direction Z, the second direction Y and the third direction X are orthogonal to each other, and the dimensions of the main unit 410 and the storage batteries 420 in the first direction X, the second direction Y and the third direction Z are similar, i.e., there is almost no difference between the dimension of the main unit 410 and the dimensions of the storage batteries 420. For example, the main unit 410 and the storage batteries 420 are rectangular bodies with similar specifications. Based on this, the front plate 411 and the back plate 421 are both sheet-like plates extending along a plane perpendicular to the first direction Z, and the bottom plate 431 is a sheet-like plate extending along a plane perpendicular to the third direction Z, which is conducive to making the U-shaped plate including the front plate 411, the back plate 421 and the bottom plate 431 fit to the surface of the UPS 400 including the main unit 410 and the storage batteries 420, so as to further reduce the overall size of the UPS 400 while accommodating the UPS 400 with the U-shaped plate, thereby facilitating reducing the layout space to be occupied by the UPS 400 in the electrical cabinet.

In some embodiments, the first direction Z is parallel to the horizontal plane, and the respective pressing plate 451 is located at the top of the main unit 410 and the storage batteries 420 in the third direction X. That is, the respective pressing plate 451 is placed horizontally, and the front plate 411 and the back plate 421 are placed vertically. In this way, it is more convenient for the operator to insert the respective pressing plate 451 into the respective insertion hole 421a or pull the respective pressing plate 451 out of the respective insertion hole 421a.

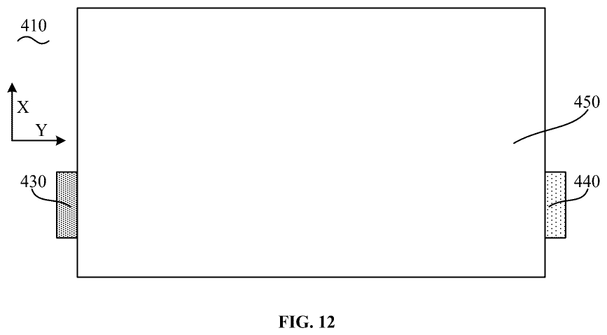

In some embodiments, referring to FIG. 11 and FIG. 12, the main unit 410 may include an air intake device 430, an air exhaust device 440, and a main body 450. The air intake device 430 and the air exhaust device 440 are disposed on opposite sides of the main body 450 along the second direction Y, where the second direction Y is the arrangement direction of the pressing plates 451. A housing formed by the front plate 411, the back plate 421 and the bottom plate 431 exposes the air intake device 430 and the air exhaust device 440.

FIG. 12 is a simple block diagram of the main unit in the UPS according to embodiments of the present disclosure.

It is noted that, with reference to FIG. 11, the main body 450 is also provided with a number of interfaces 450a on opposite sides of the main body 450 along the second direction Y. When the UPS 400 is in an operating state, a number of input signal lines and output signal lines are electrically connected to different interfaces 450a. The main unit 410 is configured to continuously receive and output signals through the input signal lines and output signal lines, and thus the main unit 410 itself generates much heat. Based on this, the air intake device 430 and the air exhaust device 440 are provided on opposite sides of the main unit 410 along the second direction Y, which is conducive to cooling the main unit 410 through the cooperation of the air intake device 430 and the air exhaust device 440, so as to avoid affecting the performance of the main unit 410 due to its own high temperature, as well as affecting the performance of the storage batteries 420 adjacent to the main unit 410. Thereby, it is conducive to the cooling of the main unit 410 through the air intake device 430 and the air exhaust device 440 to improve the service life of the main unit 410 and the service life of the storage batteries 420.

In addition, the housing formed by the front plate 411, the back plate 421 and the bottom plate 431 exposes the air intake device 430 and the air exhaust device 440, in other words, when designing the housing formed by the front plate 411, the back plate 421 and the bottom plate 431, it is avoided that the housing causes obstruction to the air intake device 430 and the air exhaust device 440 on the main unit 410, to avoid that the cold air flow from the air intake device 430 into the interior of the main unit 410 is blocked and that the hot air flow in the main unit 410 is blocked when discharged from the air exhaust device 440, thereby facilitates ensuring a relative high exchange rate between the hot and cold air flows in the main unit 410 and further ensuring a good heat dissipation effect of the air intake device 430 and the air exhaust device 440 on the main unit 410. Thereby, it is conducive to preventing the housing formed by the front plate 411, the back plate 421 and the bottom plate 431 from affecting the heat dissipation effect of the air intake device 430 and the air exhaust device 440 on the air exhaust device 440 while using the housing formed by the front plate 411, the back plate 421 and the bottom plate 431 to achieve the relative fixation of the main unit 410 and the storage batteries 420, so as to ensure that the UPS 400 has a long service life.

In some embodiments, the air intake device 430 may be an intake fan, and the air exhaust device 440 may be an exhaust fan.

The positional relationship between the air intake device 430 and the air exhaust device 440 and the main body 450 includes at least two kinds of cases below.

In some cases, referring to FIG. 7 or FIG. 11, the air exhaust device 440 is disposed at an end of the main body 450 away from the bottom plate 431 along the third direction X, in other words, the air exhaust device 440 is disposed in a top region of the main body 450. Thus, most of the interfaces 450a in the main body 410 are located at the end of the main body 450 adjacent to the bottom plate 431, which is conductive to shorten the wiring distance between cables and the interfaces 450a to facilitate the routing of the UPS 40 when the cables electrically connected to the UPS 400 are laid out at the lower part of the UPS 400 along the third direction X.

In other cases, referring to FIG. 12, the air exhaust device 440 is disposed at an end of the main body 450 adjacent to the bottom plate 431 along the third direction X, in other words, the air exhaust device 440 is disposed at a bottom region of the main body 450.

It is to be noted that with reference to FIG. 12, the air intake device 430 and the air exhaust device 440 may be directly opposite to each other along the second direction Y. In other words, the air intake device 430 and the air exhaust device 440 are equally spaced from the bottom plate 431 along the third direction X. In addition, although the air intake device is not illustrated in FIG. 7 and FIG. 11, the air intake device and the air exhaust device 440 may also be directly opposite to each other along the second direction Y in the examples shown in FIG. 7 and FIG. 11.

In some embodiments, referring to FIG. 7, the cabinet body of the electrical cabinet is provided with a number of air exhaust holes 405 in an area of the cabinet body at least directly opposite to the air exhaust device 440 of the main unit 410 along the second direction Y, and a number of air intake holes (not shown) in an area of the cabinet body at least directly opposite to the air intake device 430 of the main unit 410 along the second direction Y, so that an external cold air flow can enter the electrical cabinet through the air intake holes to cool the interior of the electrical cabinet, and a hot air flow inside the electrical cabinet can be discharged through the air exhaust holes 405.

It should be noted that FIG. 7 shows only an example of one arrangement of the air exhaust holes 405 on the cabinet body of the electrical cabinet, and the embodiments of the present disclosure do not exhaust the number and arrangement of the air exhaust holes 405 on the cabinet body of the electrical cabinet. In addition, the air intake holes may have the same style as the air exhaust holes 405 illustrated in FIG. 7.

In some embodiments, the main unit 410 may further include: a display screen (not shown) disposed on one of two opposing sides of the main unit 410 along the second direction Y, and a number of buttons (not shown) disposed below the display screen along the third direction X. The housing formed by the front plate 411, the back plate 421 and the bottom plate 431 further exposes the display screen and the buttons. In this way, when the operator needs to view the display screen on the main unit 410 or needs to operate the buttons on the main unit 410, the operator can view the display screen or operate the buttons directly without disassembling the housing formed by the front plate 411, the back plate 421 and the bottom plate 431, which is conducive to improving the convenience of the operator in operating the UPS 400.

In summary, in the embodiments of the present disclosure, a new structure for installing and fixing the UPS 400 is designed, and the convenience for the operator to achieve the mutual limitation of the respective pressing plate 451 with the front plate 411 and the back plate 421 is improved, so as to improve the convenience of the operator in installing the UPS 400 in the electrical cabinet. In addition, when the UPS 400 installed in the electrical cabinet is to be serviced or replaced, since the front plate 411 is closer to the cabinet door of the electrical cabinet than the back plate 421, the operator can remove the respective pressing plate 451 from the front plate 411 at the cabinet door, and then take away the respective pressing plate 451 on the top of the UPS 400 by pulling the respective pressure plate 451 out of the respective insertion hole 421a in the first direction X without direct contact with the back plate, which facilitates servicing or replacing the UPS 400 by the operator from the top of the UPS 400, thereby contributing to improving the convenience of the operator in removing the respective pressing plate 451 and the convenience of the operator in servicing or replacing the UPS 400.

Another embodiment of the present disclosure provides an energy storage container. Referring to FIG. 7, the energy storage container includes the electrical cabinet according to the embodiments of the present disclosure. It is to be noted that parts identical or corresponding to those in the preceding embodiments are not repeated herein.

In some embodiments, referring to FIG. 7, the first direction Z, i.e., the cabinet depth direction of the electrical cabinet, is an arrangement direction of the battery clusters (not shown) in the energy storage container. In other words, the plurality of rows of battery clusters are arranged along the first direction Z. As can be seen from the foregoing embodiments, with combined reference to with FIG. 7 and FIG. 10, the electrical cabinet provided in the embodiments of the present disclosure facilitates improving the convenience of the operator in installing and removing the UPS 400 in the electrical cabinet, and thus facilitates improving the convenience of the operator in installing and removing the UPS 400 in the energy storage container.

In some embodiments, the main unit 410 and the storage batteries 420 in the UPS 400 are arranged in the first direction Z so that the uniform design of the installation and removal process of the UPS with a different type can be achieved, and it is conductive to reducing the cabinet depth of the electrical cabinet to reduce the overall size of the electrical cabinet so as to make the energy storage container have more space to lay out the battery clusters. In this way, without changing the dimensions of the energy storage container, it is conductive to increasing the number of columns of battery clusters arranged in the energy storage container along the first direction Z while using a relatively small layout space to accommodate the UPS device, thereby facilitating increasing the energy storage density of the energy storage container without changing the dimensions of the energy storage container.

In some embodiments, each battery cluster includes a plurality of energy storage battery cells (not shown) arranged along the third direction X.

In some embodiments, the energy storage container has an electrical accommodating compartment, and a small air conditioner is provided in the electrical accommodating compartment. When the UPS 400 is located in the electrical cabinet shown in FIG. 7, the electrical cabinet shown in FIG. 7 may be located in the electrical accommodating compartment of the energy storage container so that a cold air flow in the electrical accommodating compartment of the energy storage container that is cooled by the small air conditioner may enter the electrical cabinet through a number of air intake holes to cool the interior of the electrical cabinet, and a hot air flow in the interior of the electrical cabinet can enter the electrical accommodating compartment of the energy storage container through a number of air exhaust holes 405, so as to cool the hot air flow by using the small air conditioner in the electrical accommodating compartment of the energy storage container.

According to some embodiments of the present disclosure, the following examples are provided.

In some examples, there is provided an electrical cabinet configured to house an uninterruptible power supply (UPS). The electrical cabinet includes: a front plate and a back plate oppositely arranged along a first direction, a bottom plate connecting the front plate to the back plate, and at least one pressing plate located on a top surface of the front plate away from the bottom plate. The first direction is a cabinet depth direction of the electrical cabinet, and the front plate is closer to a cabinet door of the electrical cabinet than the back plate. The front plate, the back plate and the bottom plate define an accommodating chamber, and the UPS is located in the accommodating chamber. The front plate has at least one first screw hole at a top of the front plate away from the bottom plate, and the back plate has at least one insertion hole at a top of the back plate away from the bottom plate. One end of a respective pressing plate of the at least one pressing plate is fixed to the front plate by mating of a respective first screw hole of the at least one first screw hole with a corresponding screw, and another end of the respective pressing plate is passed through a respective insertion hole of the at least one insertion hole to achieve position limiting of the pressing plate by the back plate through the respective insertion hole.

In some examples, the at least one insertion hole is in one-to-one correspondence with the at least one pressing plate, with a spacing between adjacent pressing plates of the at least one pressing plate.

In some examples, the electrical cabinet further includes a first rail, a second rail and a third rail. The first rail has one end fixed to the front plate and another end fixed to the back plate. The second rail is mounted on the first rail, and the third rail is mounted on the second rail and fixed to a cabinet body of the electrical cabinet.

In some examples, the front plate has two first bent portions oppositely arranged along a second direction, each respective first bent portion of the two first bent portions is bent towards the back plate, the second direction is an arrangement direction of the at least one pressing plate, and the respective first bent portion has at least one second screw hole. The back plate has two second bent portions oppositely arranged along the second direction, each respective second bent portion of the two second bent portions is bent towards the front plate, and the respective second bent portion has at least one third screw hole. One end of the first rail is fixed to the front plate by mating of the at least one second screw hole with a corresponding screw, and another end of the first rail is fixed to the back plate by mating of the at least one third screw hole with a corresponding screw.

In some examples, the electrical cabinet further includes a self-locking mechanism. The self-locking mechanism is located at an end of the first rail away from the front plate and the back plate.

In some examples, one end of the respective pressing plate fixed to the front plate is provided with a first mounting ear bent towards the bottom plate, the first mounting ear has at least one fourth screw hole corresponding one-to-one with the at least one first screw hole, a corresponding screw penetrates a respective fourth screw hole of the at least one fourth screw hole and a respective first screw hole of the at least one first screw hole successively to achieve fixation of the pressing plate to the front plate. Another end of the respective pressing plate inserted into the back plate is provided with a second mounting ear bent in a direction away from the bottom plate, and the second mounting ear is passed through the respective insertion hole to achieve position limiting of the respective pressing plate.

In some examples, the respective pressing plate further includes a main body disposed between the first mounting ear and the second mounting ear. The main body has spaced mounting holes, and respective screws are passed through the mounting holes to achieve fixation of the respective pressing plate to the UPS.

In some examples, the electrical cabinet further includes the UPS disposed between the front plate and the back plate and between the at least one pressing plate and the bottom plate. The UPS includes a main unit and storage batteries arranged in the first direction.

In some examples, the main unit includes an air intake device, an air exhaust device and a main body. The air intake device and the air exhaust device are arranged on opposite sides of the main body along the second direction, the second direction being the arrangement direction of the at least one pressing plate. A housing formed by the front plate, the back plate and the bottom plate exposes the air intake device and the air exhaust device.

In some examples, there is provided an energy storage container including the electrical cabinet as described above.

A person of ordinary skill in the art should appreciate that that the preceding implementations are specific embodiments for implementing the present disclosure, and in practice, various changes may be made in the form and details without departing from the spirit and scope of the embodiments of the present disclosure. Any person skilled in the art may make variations and modifications without departing from the spirit and scope of the embodiments of the present disclosure. Therefore, the protection scope of the embodiments of the present disclosure shall be defined by the appended claims.

What is claimed is:

1. An electrical cabinet for an energy storage system, comprising:
a cabinet body;
a first mounting plate, including a first fixed end and a first rotating end, wherein the first fixed end has one end fixed to the cabinet body, and the first rotating end is rotatable around the first fixed end; and
a second mounting plate, located below the first mounting plate and including a second fixed end and a second rotating end, wherein the second fixed end has one end fixed to the cabinet body, the second rotating end is rotatable around the second fixed end, and the second mounting plate is configured to move away from the first mounting plate in response to being rotated.

2. The electrical cabinet of claim 1, wherein the first mounting plate is configured to move toward the second mounting plate in response to being rotated, the first mounting plate is configured to mount alternating current devices and direct current devices, and the second mounting plate is configured to mount alternating current protectors and direct current protectors.

3. The electrical cabinet of claim 1, further comprising:
a power supply module, located at a first corner of the first mounting plate;
a switch, located at a second corner of the first mounting board, wherein the switch and the power supply module are located on a same side of the first mounting plate;
an input/output (I/O) module, located at a third corner of the first mounting board, wherein the I/O module and the switch are located on different sides of the first mounting plate; and
a relay, located at a fourth corner of the first mounting plate, wherein the relay and the I/O module are located on a same side of the first mounting plate.

4. The electrical cabinet of claim 3, further comprising:
a first terminal block, fixed to the first mounting plate and located between the power supply module and the I/O module; and
a second terminal block, fixed to the first mounting plate and located between the switch and the relay.

5. The electrical cabinet of claim 1, further comprising:
a plurality of first binding rods, mounted on the second mounting plate, wherein the plurality of first binding rods extend in a direction oriented from the first mounting plate to the second mounting plate, are arranged in a direction perpendicular to the direction oriented from the first mounting plate to the second mounting plate, and divide a mounting region on the second mounting plate into a first mounting region, a second mounting region and a third mounting region arranged at intervals in sequence; and
a second binding rod, mounted on the second mounting plate, wherein the second binding rod extends in the direction perpendicular to the direction oriented from the first mounting plate to the second mounting plate, and is located on a side of the plurality of first binding rods away from the first mounting plate.

6. The electrical cabinet of claim 5, further comprising:
a plurality of direct current fuses, fixed in the first mounting region of the second mounting plate and arranged in the direction oriented from the first mounting plate to the second mounting plate;
a plurality of alternating current fuses, fixed in the second mounting region of the second mounting plate and arranged in the direction oriented from the first mounting plate to the second mounting plate;
a plurality of direct current surge protectors, fixed in the third mounting region of the second mounting plate and arranged in the direction oriented from the first mounting plate to the second mounting plate; and
an alternating current surge protector, fixed in the third mounting region of the second mounting plate and located between adjacent ones of the plurality of direct current surge protectors.

7. The electrical cabinet of claim 1, wherein the first fixed end includes a damping hinge configured to slow a rotation rate of the first mounting plate.

8. The electrical cabinet of claim 7, wherein the second fixed end includes a damping hinge configured to slow a rotation rate of the second mounting plate.

9. The electrical cabinet of claim 1, wherein the second fixed end includes a damping hinge configured to slow a rotation rate of the second mounting plate.

10. The electrical cabinet of claim 1, wherein the first rotating end includes a fixture detachably connected to the cabinet body and configured to be disconnected from the cabinet body in response to the first mounting plate being to be rotated.

11. The electrical cabinet of claim 10, wherein the second rotating end includes a fixture detachably connected to the cabinet body and configured to be disconnected from the cabinet body in response to the second mounting plate being to be rotated.

12. The electrical cabinet of claim 1, wherein the second rotating end includes a fixture detachably connected to the cabinet body and configured to be disconnected from the cabinet body in response to the second mounting plate being to be rotated.

13. The electrical cabinet of claim 10, wherein the fixture of the first rotating end includes a screw configured to be taken out in response to the first mounting plate being to be rotated.

14. The electrical cabinet of claim 11, wherein the fixture of the second rotating end includes a screw configured to be taken out in response to the second mounting plate being to be rotated.

15. The electrical cabinet of claim 12, wherein the fixture of the second rotating end includes a screw configured to be taken out in response to the second mounting plate being to be rotated.

16. The electrical cabinet of claim 1, further comprising:
a handle fixed on a side of the first mounting plate adjacent to the first rotating end.

17. The electrical cabinet of claim 16, further comprising:
a handle fixed on a side of the second mounting plate adjacent to the second rotating end.

18. The electrical cabinet of claim 1, further comprising:
a handle fixed on a side of the second mounting plate adjacent to the second rotating end.

19. An energy storage container, comprising an electrical cabinet, wherein the electrical cabinet includes:
a cabinet body;
a first mounting plate, including a first fixed end and a first rotating end, wherein the first fixed end has one end fixed to the cabinet body, and the first rotating end is rotatable around the first fixed end; and
a second mounting plate, located below the first mounting plate and including a second fixed end and a second rotating end, wherein the second fixed end has one end fixed to the cabinet body, the second rotating end is rotatable around the second fixed end, and the second mounting plate is configured to move away from the first mounting plate in response to being rotated.

20. The energy storage container of claim 19, wherein the first mounting plate is configured to move toward the second mounting plate in response to being rotated, the first mounting plate is configured to mount alternating current devices and direct current devices, and the second mounting plate is configured to mount alternating current protectors and direct current protectors.
